(19) United States
(12) Patent Application Publication
(10) Pub. No.: US 2006/0009008 A1
(43) Pub. Date: Jan. 12, 2006

(54) Method for the laser processing of a wafer

(75) Inventors: Yasuomi Kaneuchi, Tokyo (JP); Yukio Morishige, Tokyo (JP); Satoshi Genda, Tokyo (JP); Satoshi Kobayashi, Tokyo (JP); Toshio Tsuchiya, Tokyo (JP); Ryugo Oba, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/175,155

(22) Filed: Jul. 7, 2005

(30) Foreign Application Priority Data
Jul. 12, 2004 (JP) 2004-204879

(51) Int. Cl. H01L 21/301; B23K 26/38

(52) U.S. Cl. 438/463; 219/121.72

(57) ABSTRACT

A method for the laser processing of a wafer having a plurality of devices which are composed of a laminate consisting of an insulating film and a functional film on the front surface of a substrate, the method comprising applying a pulse laser beam along streets for sectioning the plurality of devices to form grooves along the streets, wherein a pulse width of the pulse laser beam is set to 100 to 1,000 ns.

The present invention relates to a method for the laser processing of a semiconductor wafer by applying a laser beam along streets formed on the front surface of the semiconductor wafer.

### DESCRIPTION OF THE PRIOR ART

As is known to people of ordinary skill in the art, a semiconductor wafer having a plurality of semiconductor chips such as IC's or LSI's, which are formed in a matrix on the front surface of a semiconductor substrate such as a silicon substrate or the and composed of a laminate consisting of an insulating film and a functional film is formed in the production process of a semiconductor device. The semiconductor chips thus formed are sectioned by dividing lines called “streets” in this semiconductor wafer, and individual semiconductor chips are manufactured by dividing the semiconductor wafer along the streets.

Cutting along the streets of the semiconductor wafer is generally carried out with a cutting machine called “dicer”.

This cutting machine comprises a chuck table for holding a semiconductor wafer as a workpiece, a cutting means for cutting the semiconductor wafer held on the chuck table, and a moving means for moving the chuck table and the cutting means relative to each other. The cutting means comprises a rotary spindle which is rotated at a high speed and a cutting blade mounted on the spindle. The cutting blade comprises a disk-like base and an annular edge which is mounted on the side wall peripheral portion of the base and formed by fixing diamond abrasive grains having a diameter of about 3 μm to the base by electroforming.

To improve the throughput of a semiconductor chip such as IC or LSI, a semiconductor wafer comprising semiconductor chips which are composed of a laminate consisting of a low-dielectric insulating film (Low-k film) form of a film of an inorganic material such as SiOF or BSG (SiOB) or a film of an organic material such as a polyimide-based or parylene-based polymer and a functional film for forming circuits on the front surface of a semiconductor substrate such as a silicon substrate or the like has recently been implemented.

A semiconductor wafer having a metal pattern called “test element group (TEG)” which is partially formed on the streets of the semiconductor wafer, to check the function of each circuit before the semiconductor wafer is divided has also been implemented.

Because of a difference in a material of the above Low-k film or test element group (TEG) from that of the wafer, it is difficult to cut the wafer together with them at the same time with the cutting blade. That is, as the Low-k film is extremely fragile like mica, when the above semiconductor wafer having a Low-k film laminated thereon is cut along the streets with the cutting blade, a problem arises that the Low-k film peels off and this peeling reaches the circuits, thereby causing a fatal damage to the semiconductor chips. Also, as the test element group (TEG) is made of a metal, when the semiconductor wafer having the test element group (TEG) is cut with the cutting blade, a problem occurs in that a burr is produced and the service life of the cutting blade is shortened.

To solve the above problems, a processing machine for applying a pulse laser beam along the streets of the semiconductor wafer to remove the Low-k film forming the streets and the test element group (TEG) formed on the streets and then, positioning the cutting blade in the areas where the Low-k film or TEG has been removed, to cut the semiconductor wafer is disclosed by JP-A 2003-320466.

Although grooves are formed when the pulse laser beam is applied along the streets of the wafer to melt and evaporate the laminate consisting of an insulating film and a functional film, peeling of the laminate may occur on the both sides of the groove at this moment.

### SUMMARY OF THE INVENTION

It is an object of the present invention to provide a method for the laser processing of a wafer having a plurality of devices which are composed of a laminate consisting of an insulating film and a functional film on the front surface of a semiconductor substrate such as a silicon substrate or the like, the method which comprises applying a pulse laser beam along streets for sectioning the wafer to form grooves and is capable of suppressing peeling of the laminate, even if it occurs on the both sides of the grooves, to a level that it exerts substantially no influence on the devices.

According to the present invention, the above object can be attained by a method for the laser processing of a wafer having a plurality of devices which are composed of a laminate consisting of an insulating film and a functional film on the front surface of a substrate, the method comprising applying a pulse laser beam to the wafer along streets for sectioning the plurality of devices to form grooves along the streets, wherein
a pulse width of the pulse laser beam is set to 100 to 1,000 ns.

The above pulse width is preferably set to 200 to 500 ns.

Since the pulse width of the pulse laser beam is set to 100 to 1,000 ns in the method for the laser processing of a wafer according to the present invention, even if the peeling of the laminate occurs on the both sides of the groove, its level is very low and exerts substantially no influence on the devices.

### BRIEF DESCRIPTION OF THE DRAWINGS

FIG. 1 is a perspective view of a semiconductor wafer to be processed by the method for the laser processing of a wafer according to the present invention;

FIG. 2 is an enlarged sectional view of the semiconductor wafer shown in FIG. 1;

FIG. 3 is a perspective view showing a state where the semiconductor wafer shown in FIG. 1 is supported onto an annular frame via a protective tape;

FIG. 4 is a perspective view of the principal section of a laser beam machine for carrying out the method for the laser processing of a wafer according to the present invention;

FIG. 5 is a block diagram schematically showing the constitution of laser beam application means provided in the laser beam machine shown in FIG. 4;

FIG. 6 is a schematic diagram for explaining the focusing spot diameter of a laser beam;

FIGS. 7(a) and 7(b) are explanatory diagrams showing an embodiment of the method for the laser processing of a wafer according to the present invention;

FIG. 8 is an enlarged sectional view of the principal section of a semiconductor wafer having grooves formed by the method for the laser processing of a wafer shown in FIGS. 7(a) and 7(b);

FIG. 9 is an explanatory diagram showing a state where peeling occurs on the both sides of the groove formed in the semiconductor wafer;

FIG. 10 is a diagram for explaining the step of cutting a semiconductor wafer along a street after grooves are formed by the method for the laser processing of a wafer according to the present invention; and

FIG. 11 is an explanatory diagram showing the cutting-feed position of a cutting blade in the cutting step shown in FIG. 10.

### DETAILED DESCRIPTION OF THE PREFERRED EMBODIMENTS

Preferred embodiments of the laser processing of a wafer according to the present invention will be described in detail hereinunder with reference to the accompanying drawings.

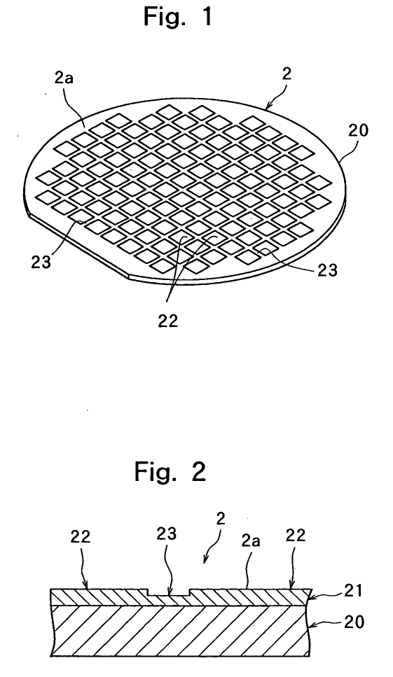

FIG. 1 is a perspective view of a semiconductor wafer as a workpiece to be processed by the method for the laser processing of a wafer according to the present invention, and FIG. 2 is an enlarged sectional view of the principal section of the semiconductor wafer shown in FIG. 1. In the semiconductor wafer 2 shown in FIG. 1 and FIG. 2, a plurality of semiconductor chips 22 (devices) such as IC's or LSI's are formed in a matrix on the front surface 20a of a semiconductor substrate 20 such as a silicon substrate or the like and composed of a laminate 21 consisting of an insulating film and a functional film for forming circuits, and the semiconductor chips 22 are sectioned by streets 23 formed in a lattice pattern. In the illustrated embodiment, the insulating film for forming the laminate 21 is an film or a low-dielectric insulating film (Low-k film) formed of a film of an inorganic material such as SiO₂, SiOF or BSG (SiOB) or a film of an organic material such as a polyimide-based and parylene-based polymer.

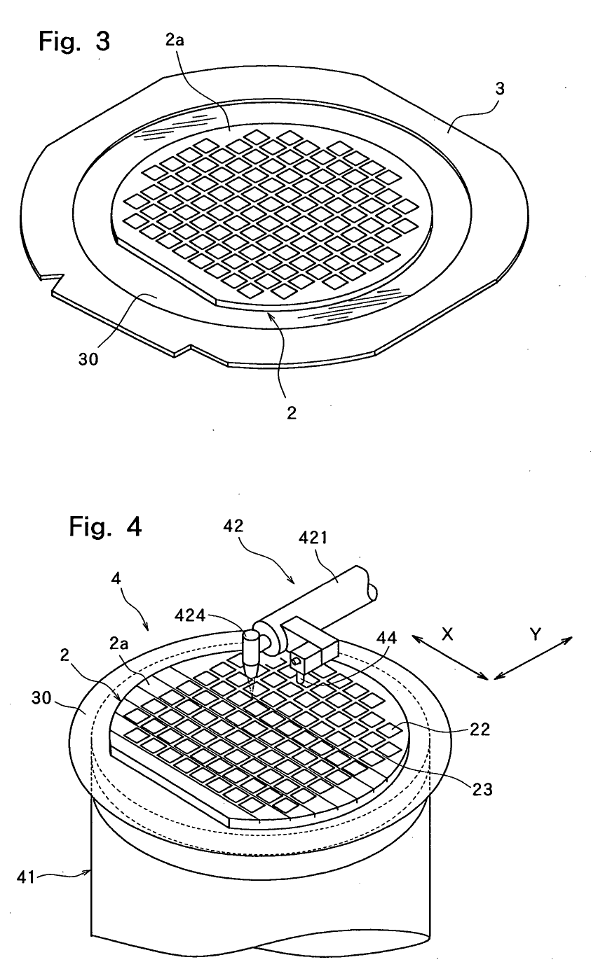

To divide the above-described semiconductor wafer 2 along the streets 23, the semiconductor wafer 2 is put on a protective tape 30 mounted on an annular frame 3, as shown in FIG. 3. At this point, the semiconductor wafer 2 is put on the protective tape 30 in such manner that the front surface 2a faces up.

Next comes the laser beam application step for applying a laser beam along the streets 23 of the semiconductor wafer 2 to remove the laminate 21 on the streets 23. This laser beam application step is carried out by using a laser beam machine 4 shown in FIGS. 4 to 7. The laser beam machine 4 shown in FIGS. 4 to 7 comprises a chuck table 41 for holding a workpiece and a laser beam application means 42 for applying a laser beam to the workpiece held on the chuck table 41. The chuck table 41 is so constituted to suction-hold the workpiece, and moved by a moving mechanism (not shown) in a processing-feed direction indicated by an arrow X and an indexing-feed direction indicated by an arrow Y in FIG. 4.

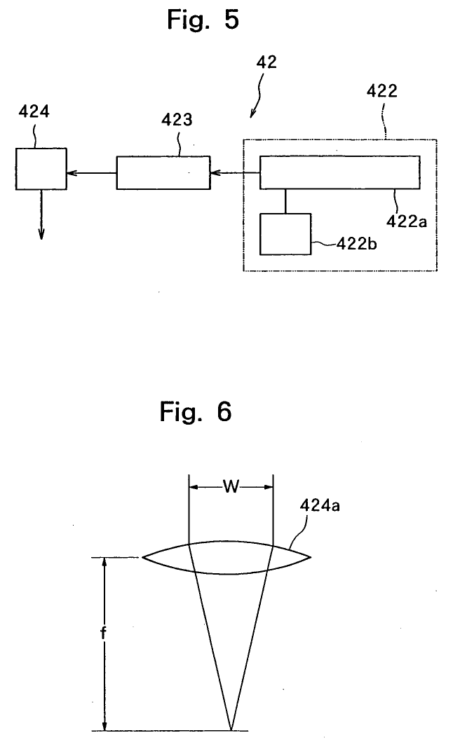

The above laser beam application means 42 has a cylindrical casing 421 arranged substantially horizontally. In the casing 421, there are installed pulse laser beam oscillation means 422 and a transmission optical system 423, as shown in FIG. 5. The pulse laser beam oscillation means 422 is constituted by a pulse laser beam oscillator 422a composed of a YAG laser oscillator or YVO4 laser oscillator and a repetition frequency setting means 422b connected to the pulse laser beam oscillator 422a. The transmission optical system 423 comprises suitable optical elements such as a beam splitter, etc. A condenser 424 housing condensing lenses (not shown) constituted by a set of lenses that may be known per se is attached to the end of the above casing 421. A laser beam oscillated from the above pulse laser beam oscillation means 422 reaches the condenser 424 through the transmission optical system 423 and is applied to the workpiece held on the above chuck table 41 from the condenser 424 at a predetermined focusing spot diameter D. This focusing spot diameter D is defined by the expression D (μm)=4×λ×f/(π×W) (wherein λ is the wavelength (μm) of the pulse laser beam, W is the diameter (mm) of the pulse laser beam applied to an objective condenser lens 424a, and f is the focusing distance (mm) of the objective condenser lens 424a) when the pulse laser beam having a Gaussian distribution is applied through the objective condenser lens 424a of the condenser 424 as shown in FIG. 6.

The illustrated laser beam machine 4 comprises an image pick-up means 44 mounted on the end of the casing 421 constituting the above laser beam application means 42, as shown in FIG. 4. This image pick-up means picks up an image of the workpiece held on the chuck table 41. The image pick-up means 44 is constituted by an optical system, an image pick-up device (CCD), etc., and transmits an image signal to a control means that is not shown.

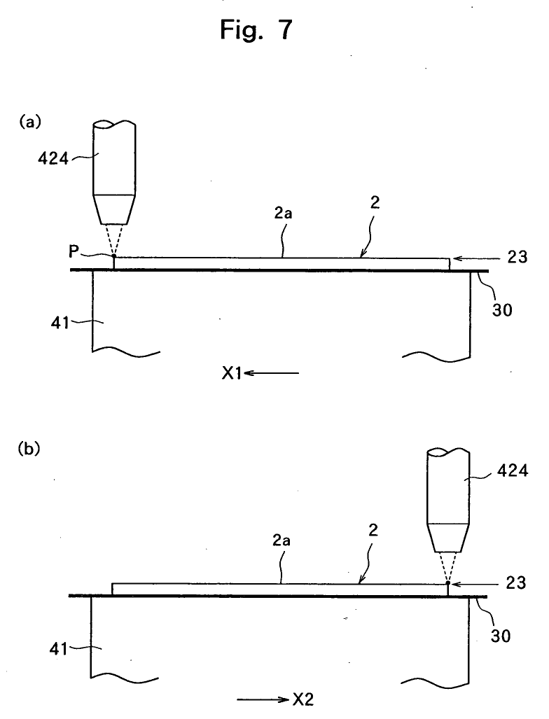

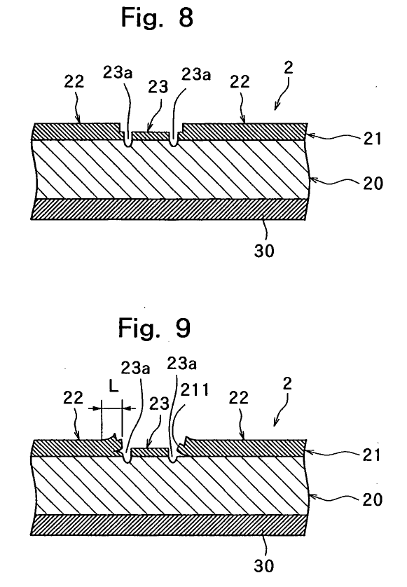

The laser beam application step which is carried out by using the above laser beam machine 4 will be described with reference to FIG. 4, FIGS. 7(a) and 7(b) and FIG. 8.

In this laser beam application step, the semiconductor wafer 2 is first placed on the chuck table 41 of the laser beam machine 4 shown in FIG. 4 and is suction-held on the chuck table 41. At this point, the semiconductor wafer 2 is held in such a manner that the front surface 2a faces up. In FIG. 4, the annular frame 3 having the protective tape 30 affixed thereto is omitted. The annular frame 3 is held by a suitable frame holding means of the chuck table 41.

The chuck table 41 suction-holding the semiconductor wafer 2 as described above is brought to a position right below the image pick-up means 44 by a moving mechanism that is not shown. After the chuck table 41 is positioned right below the image pick-up means 44, alignment work for detecting the area to be laser processed of the semiconductor wafer 2 is carried out by the image pick-up means 44 and the control means that is not shown. That is, the image pick-up means 44 and the control means (not shown) carry out image processing such as pattern matching, etc. to align a street 23 formed in a predetermined direction of the semiconductor wafer 2 with the condenser 424 of the laser beam application means 42 for applying a laser beam along the street 23, thereby performing the alignment of a laser beam application position. The alignment of the laser beam application position is also similarly carried out on streets 23 that are formed on the semiconductor wafer 2 and extend in a direction perpendicular to the above predetermined direction.

After the street 23 formed on the semiconductor wafer 2 held on the chuck table 41 is detected and the alignment of the laser beam application position is carried out as described above, the chuck table 41 is moved to a laser beam application area where the condenser 424 of the laser beam application means 42 for applying a laser beam is located as shown in FIGS. 7(a) and 7(b), to bring the predetermined street 23 to a position right below the condenser 424. At this point, the semiconductor wafer 2 is positioned such that one end (left end in FIG. 7(a)) of the street 23 is located right below the condenser 424, as shown in FIG. 7(a). The chuck table 41, that is, the semiconductor wafer 2 is then moved in the direction indicated by the arrow X1 in FIG. 7(a) at a predetermined processing-feed rate while a pulse laser beam is applied from the condenser 424 of the laser beam application means 42. When the other end (right end in FIG. 7(b)) of the street 23 reaches the position right below the condenser 424, as shown in FIG. 7(b), the application of the pulse laser beam is suspended and the movement of the chuck table 41, that is, the semiconductor wafer 2 is stopped. In this laser beam application step, the focusing point P of the pulse laser beam is set to a position near the surface of the street 23.

Thereafter, the chuck table 41, that is, the semiconductor wafer 2 is moved about 30 to 40 μm in the direction (the indexing-feed direction) perpendicular to the sheet. The chuck table 41, that is, the semiconductor wafer 2 is then moved in the direction indicated by the arrow X2 in FIG. 7(b) at a predetermined processing-feed rate while the pulse laser beam is applied from the condenser 424 of the laser beam application means 42. When the position shown in FIG. 7(a) is reached, the application of the pulse laser beam is suspended and the movement of the chuck table 41, that is, the semiconductor wafer 2 is stopped.

Two grooves 23a and 23a that are deeper than the thickness of the laminate 21 are formed in the street 23 of the semiconductor wafer 2 as shown in FIG. 8 by carrying out the above laser beam application step. As a result, the laminate 21 is divided by the two grooves 23a and 23a. The length between the both outer sides of two grooves 23a and 23a formed in the street 23 is set larger than the thickness of the cutting blade that will be described later. The above laser beam application step is then carried out on all the streets 23 formed on the semiconductor wafer 2. The processing quality of the grooves 23a formed by this laser beam application step is influenced by the processing conditions, particularly the pulse width of the pulse laser beam. That is, it was found that when the pulse width of the pulse laser beam is small, the peeling of the laminate 21 occurs on the outer sides of the grooves 23a and 23a, as shown in FIG. 9 and the size L of a peeling portion 211 is large.

The results of experiments on the occurrence of a peeling portion according to processing conditions are given below.

The experiments were conducted by using a laser beam machine having the following performance.
Light source of laser beam: YVO4 laser or YAG laser
Wavelength: 266 nm, 355 nm, 523 nm
Average output: 0.45 to 1.35 W
Repetition frequency: 30 to 200 kHz
Pulse width: 10 to 2,000 ns
Focusing spot diameter: 13 to 40 μm
Processing-feed rate: 15 to 400 mm/sec

In the above performance, the average output is energy of a pulse laser beam applied for 1 second, the repetition frequency is the number of pulses of the pulse laser beam applied for 1 second, and the pulse width is a time during which one pulse of the pulse laser beam is applied.

### EXPERIMENT 1:

In order to verify the influence of the processing-feed rate on the occurrence of a peeling portion, the above laser beam application step was carried out under the following processing conditions by setting the processing-feed rate to 15 mm/sec, 100 mm/sec, 200 mm/sec and 400 mm/sec to check the condition of peeling at three locations.
Wavelength: 355 nm
Average output: 0.9 W
Repetition frequency: 30 kHz
Pulse width: 10 ns
Focusing spot diameter: 20 μm

As a result of the experiment, peeling portions as large as 14 to 25 μm occurred.

### EXPERIMENT 2:

In order to verify the influence of the average output on the occurrence of a peeling portion, the above laser beam application step was carried out under the following processing conditions by setting the average output to 0.45 W, 0.9 W and 1.35 W to check the condition of peeling at three locations.
Wavelength: 355 nm
Repetition frequency: 30 kHz
Pulse width: 10 ns
Focusing spot diameter: 20 μm
Processing-feed rate: 100 mm/sec

As a result of the experiment, peeling portions as large as 16 to 25 μm occurred.

### EXPERIMENT 3:

In order to verify the influence of the repetition frequency on the occurrence of a peeling portion, the above laser beam application step was carried out under the following processing conditions by setting the repetition frequency to 30 kHz, 60 kHz, 90 kHz and 150 kHz to check the condition of peeling at three locations.
Wavelength: 355 nm
Average output: 0.9 W
Pulse width: 10 ns
Focusing spot diameter: 20 μm
Processing-feed rate: 100 mm/sec

As a result of the experiment, peeling portions as large as 14 to 27 μm occurred.

### EXPERIMENT 4:

In order to verify the influence of the focusing spot diameter on the occurrence of a peeling portion, the above laser beam application step was carried out under the following processing conditions by setting the focusing spot diameter to 13 μm, 20 μm and 40 μm to check the condition of peeling at three locations.
Wavelength: 355 nm
Average output: 0.9 W
Repetition frequency: 30 kHz
Pulse width: 10 ns
Processing-feed rate: 100 mm/sec

As a result of the experiment, peeling portions as large as 13 to 26 μm occurred.

### EXPERIMENT 5:

In order to verify the influence of the pulse width on the occurrence of a peeling portion, the above laser beam application step was carried out under the following processing conditions by setting the pulse width to 10 ns, 50 ns, 100 ns, 200 ns, 500 ns, 1,000 ns and 1,200 ns to check the condition of peeling at three locations.
Wavelength: 355 nm
Average output: 0.9 W
Repetition frequency: 30 kHz
Focusing spot diameter: 20 μm
Processing-feed rate: 100 mm/sec

As a result of the experiments, when the pulse width was 10 ns, peeling portions as large as 13 to 26 μm occurred and when the pulse width was 50 ns, peeling portion as large as 10 to 13 μm occurred. It was found that when the pulse width was 100 ns, peeling portions were as large as 10 μm or less, which means that the above pulse width has substantially no influence on the devices. When the pulse width was 200 ns, peeling portions were as large as 5 μm or less and when the pulse width was 500 ns, peeling portions were as large as 2 μm or less. When the pulse width was 1,000 ns and 1,200 ns, peeling portions did not occur. Thus, it was found that as the pulse width increases, peeling portions become smaller in size. However, it was also found that when the pulse width is larger than 1,000 ns, the influence of heat appears, resulting in lowering in the quality of the devices.

It can be understood from the results of the above experiments that the processing conditions other than the pulse width have little influence on the occurrence of peeling and the size of a peeling portion. When the pulse width is set to 100 ns, a peeling portion is as large as 10 μm or less and when the pulse width is set to 200 ns, a peeling portion is as large as 5 μm or less, which means that the pulse width has substantially no influence on the devices. Therefore, in consideration of the influence of heat, the pulse width is preferably set to 100 to 1,000 ns, more preferably to 200 to 500 ns.

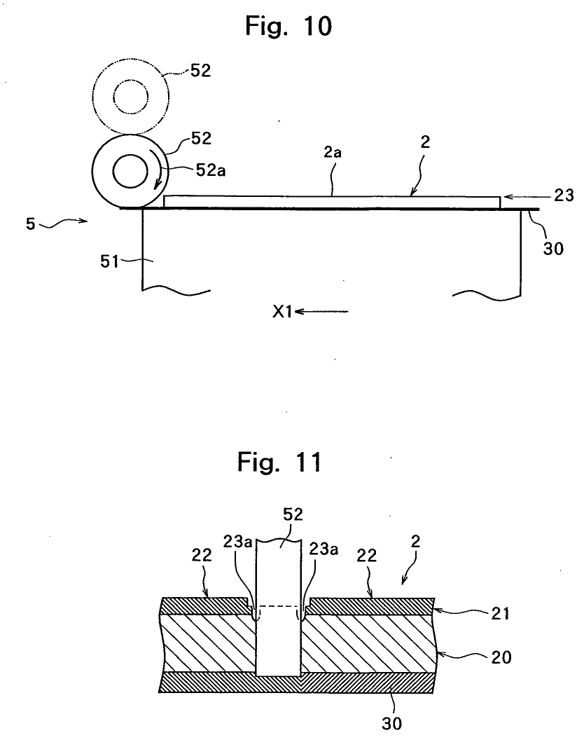

After the above laser beam application step is carried out on all the streets 23 formed on the semiconductor wafer 2, the step of cutting the semiconductor wafer 2 along the streets 23 is carried out. That is, as shown in FIG. 10, the semiconductor wafer 2 which has been subjected to the laser beam application step is placed on the chuck table 51 of a cutting machine 5 in such a manner that the front surface 2a faces up and is held on the chuck table 51 by a suction means that is not shown. The chuck table 51 holding the semiconductor wafer 2 is then moved to the cutting start position of the area to be cut. At this point, the semiconductor wafer 2 is positioned such that one end (left end in FIG. 10) of the street 23 locates on the right side a predetermined distance from right below the cutting blade 52, as shown in FIG. 10.

After the chuck table 51, that is, the semiconductor wafer 2 is thus brought to the cutting start position of the area to be cut, the cutting blade 52 is moved down from its standby position shown by a two-dot chain line in FIG. 10 to a predetermined cutting-feed position shown by a solid line in FIG. 10. This cutting-feed position is set to a position where the lower end of the cutting blade 52 reaches the protective tape 30 affixed to the back surface of the semiconductor wafer 2, as shown in FIG. 11.

Thereafter, the cutting blade 52 is rotated in the direction indicated by the arrow 52a at a predetermined revolution and the chuck table 51, that is, the semiconductor wafer 2 is moved in the direction indicated by the arrow X1 in FIG. 10 at a predetermined cutting-feed rate. When the other end (right end in FIG. 10) of the chuck table 51, that is, the semiconductor wafer 2 reaches a position on the left side a predetermined distance from right below the cutting blade 52, the movement of the chuck table 51, that is, the semiconductor wafer 2 is stopped. By thus cutting-feeding the chuck table 51, that is, the semiconductor wafer 2, the semiconductor wafer 2 is cut along the street 23. When the two grooves 21a and 21a are cut with the cutting blade 52, the laminate 21 remaining between the two grooves 21a and 21a is cut away with the cutting blade 52. However, as both sides of the laminate 21 are separated from the chips 22 by the two grooves 21a and 21a, the laminate 21 does not affect the chips 22, even if it peels off.

Thereafter, the chuck table 51, that is, the semiconductor wafer 2 is moved a distance corresponding to the interval between streets 23 in the direction (indexing-feed direction) perpendicular to the sheet, and the street 23 to be cut next is located at a position corresponding to the cutting blade 52 and returned to the state shown in FIG. 10. The cutting step is then carried out in the same manner as described above.

The above cutting step is carried out under the following processing conditions, for example.
Cutting blade: outer diameter of 52 mm, thickness of 30 μm
Revolution of cutting blade: 40,000 rpm
Cutting-feed rate: 50 mm/sec

The above cutting step is carried out on all the streets 23 formed on the semiconductor wafer 2. As a result, the semiconductor wafer 2 is cut along the street 23 to be divided into individual semiconductor chips.

What is claimed is:

1. A method for the laser processing of a wafer having a plurality of devices which are composed of a laminate consisting of an insulating film and a functional film on the front surface of a substrate, the method comprising applying a pulse laser beam along streets for sectioning the plurality of devices to form grooves along the streets, wherein
a pulse width of the pulse laser beam is set to 100 to 1,000 ns.

2. The method for the laser processing of a wafer according to claim 1, wherein the pulse width is set to 200 to 500 ns.
